(19) United States
(12) Patent Application Publication
(10) Pub. No.: US 2024/0030885 A1
(43) Pub. Date: Jan. 25, 2024

(54) ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/374,117

(22) Filed: Sep. 28, 2023

Related U.S. Application Data
(63) Continuation of application No. PCT/JP2022/015385, filed on Mar. 29, 2022.
(60) Provisional application No. 63/168,309, filed on Mar. 31, 2021.
(60) Provisional application No. 63/172,552, filed on Apr. 8, 2021.

(51) Int. Cl. H03H 9/02; H03H 9/17

(52) U.S. Cl. CPC H03H 9/02015; H03H 9/172

(57) ABSTRACT

An acoustic wave device includes a piezoelectric layer, electrodes, a support substrate, a first cover section and a first support section. As viewed in a stacking direction of the support substrate and the piezoelectric layer, at least a portion of each of first and second functional electrodes overlaps a hollow portion. As viewed in the stacking direction, the first cover section overlaps the first and second functional electrodes and first and second wiring electrodes. As viewed in the stacking direction of the support substrate and the piezoelectric layer, at least a portion of a first relay electrode overlaps at least one of the first and second functional electrodes.

### CROSS REFERENCE TO RELATED APPLICATIONS

This application claims the benefit of priority to Provisional Application No. 63/172,552 filed on Apr. 8, 2021 and Provisional Application No. 63/168,309 filed on Mar. 31, 2021, and is a Continuation Application of PCT Application No. PCT/JP2022/015385 filed on Mar. 29, 2022. The entire contents of each application are hereby incorporated herein by reference.

### BACKGROUND OF THE INVENTION

### 1. Field of the Invention

The present invention relates to an acoustic wave device.

### 2. Description of the Related Art

An acoustic wave device including a piezoelectric layer made of lithium niobate or lithium tantalate is known.

Japanese Unexamined Patent Application Publication No. 2012-257019 discloses the following acoustic wave device. The acoustic wave device includes a support body, a piezoelectric substrate, and an IDT (Interdigital Transducer) electrode. A hollow portion is formed in the support body. The piezoelectric substrate is disposed on the support body so as to overlap the hollow portion. The IDT electrode is disposed on the piezoelectric substrate so as to overlap the hollow portion. A Lamb wave is excited by the IDT electrode. Peripheral edges of the hollow portion do not include any straight line extending in parallel with a propagation direction of a Lamb wave to be excited by the IDT electrode. The acoustic wave device disclosed in Japanese Unexamined Patent Application Publication No. 2012-257019 forms an acoustic wave resonator utilizing a Lamb wave.

FIG. 1 illustrates an equivalent circuit of a typical resonator.

The impedance of the resonator shown in FIG. 1 is expressed by the following equation.

$$Y = \frac{1}{Z} = j ω ( {C}_{0} - \frac{{C}_{1}}{{ω}^{2} {L}_{1} {C}_{1} - 1} )$$

In the resonator shown in FIG. 1, a damping capacitor Co without a hollow portion (with Si substrate) is 0.0739 pF, while a damping capacitor Co with a hollow portion (without Si substrate) is 0.0510 pF. That is, the damping capacitor Co with a hollow portion is reduced to 69% of the damping capacitor Co without a hollow portion.

The damping capacitor Co of a resonator is a capacitor that determines the impedance of the resonator and thus significantly influences the characteristics. In an acoustic wave device with a hollow portion, the capacitance is likely to decrease as described above, which leads to the degradation of the characteristics. When it becomes necessary to increase the capacitance to improve the characteristics, the size of a resonator is increased to achieve a required amount of capacitance. This enlarges the resulting acoustic wave device. In this manner, in an acoustic wave device having a hollow portion, it is difficult to increase the capacitance and to reduce the size of the acoustic wave device at the same time.

### SUMMARY OF THE INVENTION

Preferred embodiments of the present invention provide acoustic wave devices that are each able to increase capacitance without increasing the sizes of the acoustic wave devices.

An acoustic wave device according to a preferred embodiment of the present invention includes a piezoelectric layer, a plurality of electrodes, a support substrate, a first cover section, and a first support section. The piezoelectric layer includes a first main surface and a second main surface opposing each other. The plurality of electrodes are provided on the first main surface of the piezoelectric layer. The support substrate is stacked directly or indirectly on the second main surface of the piezoelectric layer. The first cover section is separated from the first main surface of the piezoelectric layer with a space therebetween. The first support section is provided between the first cover section and the piezoelectric layer or the support substrate. The plurality of electrodes include at least one pair of functional electrodes and wiring electrodes. Each of the wiring electrodes is connected to a corresponding functional electrode. The at least one pair of functional electrodes includes a first functional electrode and a second functional electrode facing each other in an intersecting direction. The intersecting direction is a direction intersecting with a stacking direction of the support substrate and the piezoelectric layer. The wiring electrodes include a first wiring electrode connected to the first functional electrode and a second wiring electrode connected to the second functional electrode. A hollow portion is provided between the support substrate and the piezoelectric layer. As viewed in the stacking direction of the support substrate and the piezoelectric layer, at least a portion of the first functional electrode and at least a portion of the second functional electrode overlap the hollow portion. As viewed in the stacking direction of the support substrate and the piezoelectric layer, the first cover section overlaps the first and second functional electrodes and the first and second wiring electrodes. A first relay electrode, which is to be electrically connected to the first functional electrode, and a second relay electrode, which is to be electrically connected to the second functional electrode, are provided on a main surface of the first cover section. The main surface of the first cover section is a side adjacent to or in a vicinity of the piezoelectric layer.

In an acoustic wave device according to a preferred embodiment of the present invention, as viewed in a stacking direction of a support substrate and a piezoelectric layer, at least a portion of a first relay electrode overlaps at least one of a first functional electrode and a second functional electrode. Alternatively, the first relay electrode and the second relay electrode face each other in the intersecting direction on a main surface of a first cover section, the main surface of the first cover section being a side adjacent to or in a vicinity of the piezoelectric layer, or face each other in the stacking direction of the support substrate and the piezoelectric layer.

According to preferred embodiments of the present invention, it is possible to provide acoustic wave devices that are each able to increase capacitance without increasing the sizes of the acoustic wave devices.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 illustrates an equivalent circuit of a typical resonator.

FIG. 2 is a sectional view schematically illustrating an example of an acoustic wave device according to a preferred embodiment of the present invention.

FIG. 3 is a plan view schematically illustrating an example of a relay electrode of the acoustic wave device shown in FIG. 2.

FIG. 4 is a sectional view schematically illustrating an example of an acoustic wave device according to a first preferred embodiment of the present invention.

FIG. 5 is a plan view of a piezoelectric layer and elements thereon in the region indicated by I in FIG. 4.

FIG. 6 is a plan view of a first cover section and elements thereon in the region indicated by II in FIG. 4.

FIG. 7 is a sectional view schematically illustrating an example of an acoustic wave device according to a second preferred embodiment of the present invention.

FIG. 8 is a plan view of a piezoelectric layer and elements thereon in the region indicated by I in FIG. 7.

FIG. 9 is a plan view of a first cover section and elements thereon in the region indicated by II in FIG. 7.

FIG. 10 is a sectional view schematically illustrating an example of an acoustic wave device according to a third preferred embodiment of the present invention.

FIG. 11 is a plan view of a piezoelectric layer and elements thereon in the region indicated by I in FIG. 10.

FIG. 12 is a plan view of a first cover section and elements thereon in the region indicated by II in FIG. 10.

FIG. 13 is a sectional view schematically illustrating an example of an acoustic wave device according to a fourth preferred embodiment of the present invention.

FIG. 14 is a plan view of a piezoelectric layer and elements thereon in the region indicated by I in FIG. 13.

FIG. 15 is a plan view of a first cover section and elements thereon in the region indicated by II in FIG. 13.

FIG. 16 is a sectional view schematically illustrating an example of an acoustic wave device according to a fifth preferred embodiment of the present invention.

FIG. 17 is a plan view of a piezoelectric layer and elements thereon in the region indicated by I in FIG. 16.

FIG. 18 is a plan view of a first cover section and elements thereon in the region indicated by II in FIG. 16.

FIG. 19 is a schematic perspective view illustrating the outer appearance of an example of an acoustic wave device utilizing a bulk wave of a thickness shear mode according to a preferred embodiment of the present invention.

FIG. 20 is a plan view illustrating the electrode structure on a piezoelectric layer of the acoustic wave device shown in FIG. 19.

FIG. 21 is a sectional view of a portion along line A-A in FIG. 19.

FIG. 22 is a schematic elevational cross-sectional view for explaining a Lamb wave propagating through a piezoelectric film of an acoustic wave device according to a preferred embodiment of the present invention.

FIG. 23 is a schematic elevational cross-sectional view for explaining a bulk wave of a thickness shear mode propagating through a piezoelectric film of an acoustic wave device according to a preferred embodiment of the present invention.

FIG. 24 is a diagram illustrating the amplitude direction of a bulk wave of the thickness shear mode.

FIG. 25 is a graph illustrating an example of the resonance characteristics of the acoustic wave device shown in FIG. 19.

FIG. 26 is a graph illustrating the relationship between d/2p, where d is the thickness of the piezoelectric layer and p is the center-to-center distance between adjacent electrodes, and the fractional bandwidth of an acoustic wave device as a resonator.

FIG. 27 is a plan view illustrating another example of an acoustic wave device utilizing a bulk wave of the thickness shear mode according to a preferred embodiment of the present invention.

FIG. 28 is a reference diagram illustrating an example of the resonance characteristics of the acoustic wave device shown in FIG. 19.

FIG. 29 is a diagram illustrating the relationship between the fractional bandwidth and the amount of phase shift of the impedance of a spurious response normalized at about 180 degrees, that is, the magnitude of the spurious response, when many acoustic wave resonators were provided based on a preferred embodiment of the present invention.

FIG. 30 is a graph illustrating the relationships between d/2p, the metallization ratio MR, and the fractional bandwidth.

FIG. 31 is a graph illustrating a map of the fractional bandwidth with respect to the Euler angles (0°, θ, ψ) of LiNbO₃ in a case in which d/p is approached as close to 0 as possible.

FIG. 32 is a partial cutaway perspective view for explaining an example of an acoustic wave device utilizing a Lamb wave according to a preferred embodiment of the present invention.

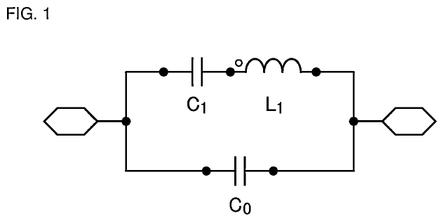

### DETAILED DESCRIPTION OF THE PREFERRED EMBODIMENTS

Acoustic wave devices according to preferred embodiments of the present invention will be described below with reference to the drawings.

An acoustic wave device according to a preferred embodiment of the present invention includes a piezoelectric layer and a plurality of electrodes provided on at least one main surface of the piezoelectric layer.

In first, second, and third aspects of a preferred embodiment of the present invention, an acoustic wave device includes a piezoelectric layer made of, for example, lithium niobate or lithium tantalate and first and second electrodes which face each other in a direction intersecting with the thickness direction of the piezoelectric layer.

In the first aspect, a bulk wave of the thickness shear mode, such as a primary thickness shear mode, is used. In the second aspect, the first electrode and the second electrode are adjacent electrodes, and d/p is set to, for example, about 0.5 or smaller, where d is the thickness of the piezoelectric layer and p is the center-to-center distance between the first and second electrodes. With this configuration, in the first and second aspects, the Q factor can be improved even if the acoustic wave device is reduced in size.

In the third aspect, a Lamb wave is used. The resonance characteristics based on the Lamb wave can be obtained.

The present invention will be described below through illustration of preferred embodiments of the present invention with reference to the drawings.

The drawings only schematically illustrate elements, and the dimensions and the scales, such as the aspect ratios, of the elements may be different from those of actual products.

The individual preferred embodiments described in the specification are only examples. The configurations of elements discussed in different preferred embodiments may be partially replaced by or combined with each other.

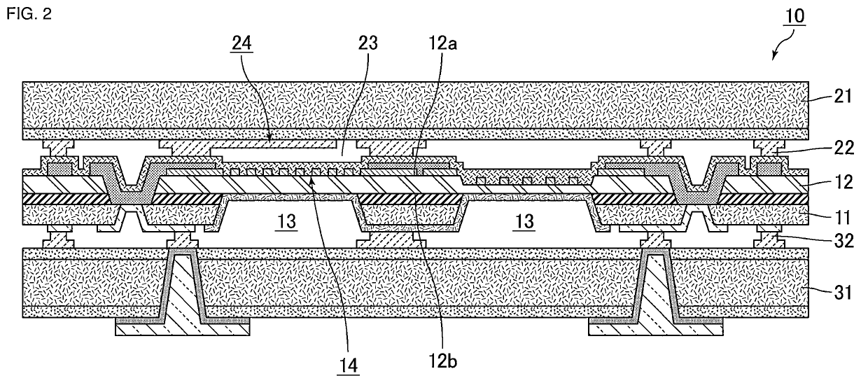

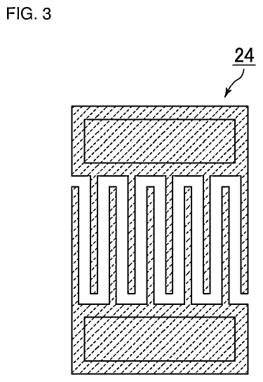

FIG. 2 is a sectional view schematically illustrating an example of an acoustic wave device according to a preferred embodiment of the present invention. FIG. 3 is a plan view schematically illustrating an example of a relay electrode which defines the acoustic wave device shown in FIG. 2.

An acoustic wave device 10 shown in FIG. 2 includes a support substrate 11 and a piezoelectric layer 12. The support substrate 11 includes a hollow portion 13 on one of its main surfaces. The piezoelectric layer 12 is provided on the main surface so as to cover the hollow portion 13. On the main surface of the piezoelectric layer 12 opposite to the surface adjacent to the support substrate 11, a plurality of electrodes (such as a functional electrode 14) are provided.

The acoustic wave device 10 also includes a first cover section 21 and a first support section 22. The first cover section 21 is separated from the piezoelectric layer 12 with a space therebetween. The first support section 22 is disposed between the first cover section 21 and the piezoelectric layer 12 or the support substrate 11. A second hollow portion 23 is provided between the first cover section 21 and the functional electrode 14.

On the main surface of the first cover section 21 on the side adjacent to the piezoelectric layer 12, a relay electrode 24, which is to be electrically connected to the functional electrode 14, is provided.

In the acoustic wave device 10, the first cover section 21 is disposed above the functional electrode 14, and also, the relay electrode 24 to be electrically connected to the functional electrode 14 is disposed on the first cover section 21 so as to overlap the functional electrode 14 as seen in a stacking direction (top-bottom direction in FIG. 2) of the support substrate 11 and the piezoelectric layer 12. In this case, it is preferable that the relay electrode 24 to be electrically connected to the functional electrode 14 is provided on the first cover section 21 so that portions of the relay electrode 24 face each other.

Alternatively, in the acoustic wave device 10, the first cover section 21 is disposed above the functional electrode 14, and also, the relay electrode 24 to be electrically connected to the functional electrode 14 may be disposed on the first cover section 21 so that portions of the relay electrode 24 face each other. In this case, it is not necessary that the relay electrode 24, which is to be electrically connected to the functional electrode 14, disposed on the first cover section 21 overlaps the functional electrode 14 as seen in the stacking direction of the support substrate 11 and the piezoelectric layer 12.

In the acoustic wave device 10, if, as seen in the stacking direction of the support substrate 11 and the piezoelectric layer 12, the relay electrode 24 is disposed to overlap the functional electrode 14 or if portions of the relay electrode 24 are disposed to face each other, or, as seen in the stacking direction of the support substrate 11 and the piezoelectric layer 12, if the relay electrode 24 is disposed to overlap the functional electrode 14 and portions of the relay electrode 24 are disposed to face each other, capacitance can be increased without increasing the size of the acoustic wave device 10.

The hollow portion 13 may pass through the support substrate 11, although this is not necessary. If the hollow portion 13 passes through the support substrate 11, the acoustic wave device 10 may also include a second cover section 31 and a second support section 32. The second cover section 31 is provided close to the surface of the support substrate 11 opposite the surface close to the piezoelectric layer 12 and encloses the hollow portion 13. The second support section 32 is provided between the second cover section 31 and the support substrate 11.

The detailed configuration of the acoustic wave device 10 shown in FIG. 2 and that of the relay electrode 24 shown in FIG. 3 will be explained in preferred embodiments of the present invention described below.

Preferred embodiments of acoustic wave devices of the present invention will be described below more specifically. However, the present invention is not restricted to these preferred embodiments.

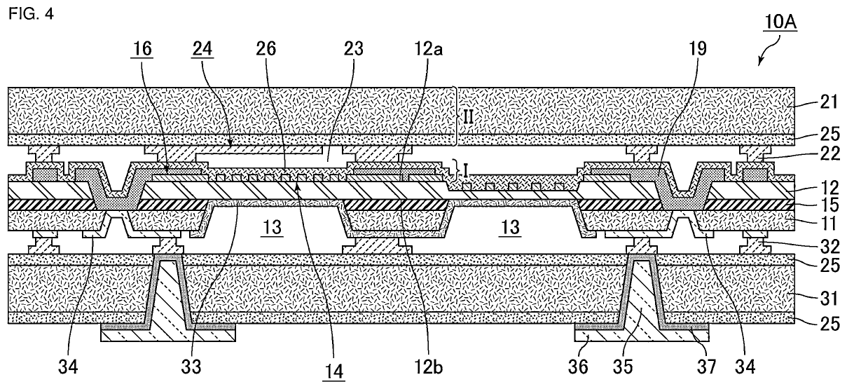

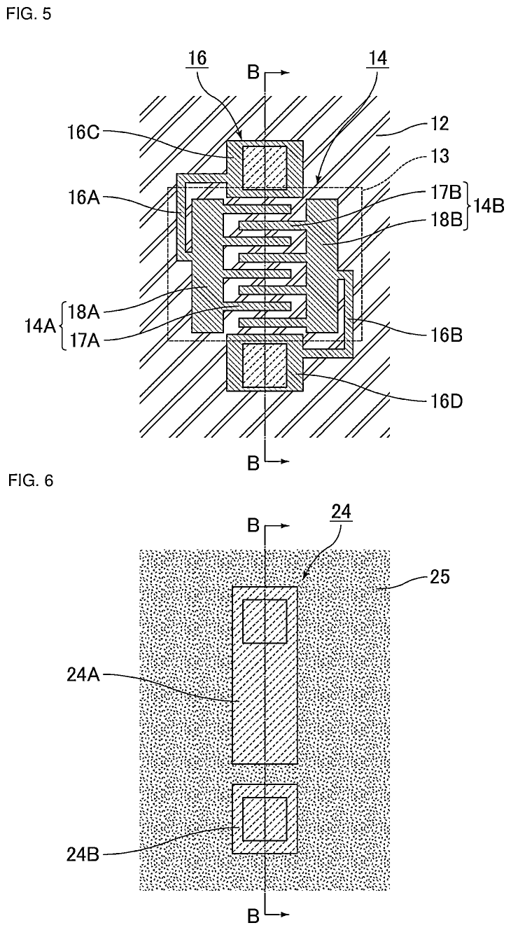

FIG. 4 is a sectional view schematically illustrating an example of an acoustic wave device according to a first preferred embodiment of the present invention. FIG. 5 is a plan view of a piezoelectric layer and elements thereon in the region indicated by I in FIG. 4. FIG. 6 is a plan view of a first cover section and elements thereon in the region indicated by II in FIG. 4. A cross section taken along line B-B in each of FIGS. 5 and 6 is shown in FIG. 4.

An acoustic wave device 10A according to the first preferred embodiment illustrated in FIGS. 4, 5, and 6 includes a support substrate 11, an intermediate layer 15 stacked on the support substrate 11, and a piezoelectric layer 12 stacked on the intermediate layer 15. The piezoelectric layer 12 includes first and second main surfaces 12a and 12b opposing each other. A plurality of electrodes (such as a functional electrode 14) are provided on the piezoelectric layer 12.

In a stacking direction (top-bottom direction in FIG. 4) of the support substrate 11 and the piezoelectric layer 12, a hollow portion 13 (hereinafter may also be referred to as a first hollow portion 13) is provided to pass through the support substrate 11 and the intermediate layer 15. The intermediate layer 15 may be omitted.

The support substrate 11 is made of, for example, silicon (Si), for example. Nevertheless, the material for the support substrate 11 is not limited to silicon. Other examples of the material for the support substrate 11 are piezoelectric materials, such as aluminum oxide, lithium tantalate, lithium niobate, and quartz, various ceramic materials, such as alumina, sapphire, silicon nitride, aluminum nitride, silicon carbide, zirconia, cordierite, mullite, steatite, and forsterite, dielectric materials, such as diamond and glass, semiconductor materials, such as gallium nitride, and resin.

The intermediate layer 15 is made of silicon oxide (SiOₓ), for example. In this case, the intermediate layer 15 may be made of, for example, SiO₂. The material for the intermediate layer 15 is not limited to silicon oxide. Silicon nitride (SiₓN_{y}), for example, may also be used. In this case, the intermediate layer 15 may be made of, for example, Si₃N₄.

The piezoelectric layer 12 is made of, for example, lithium niobate (LiNbOₓ) or lithium tantalate (LiTaOₓ) In this case, the piezoelectric layer 12 may be made of, for example, LiNbO₃ or LiTaO₃.

The plurality of electrodes include at least one pair of functional electrodes 14 and a plurality of wiring electrodes 16. Each of the wiring electrodes 16 is connected to a corresponding functional electrode 14.

As illustrated in FIG. 5, the functional electrode 14 includes, for example, first electrodes 17A (hereinafter may also referred to as first electrode fingers 17A) and second electrodes 17B (hereinafter may also referred to as second electrode fingers 17B) facing each other, a first busbar electrode 18A, and a second busbar electrode 18B. The first electrodes 17A are connected to the first busbar electrode 18A. The second electrodes 17B are connected to the second busbar electrode 18B. The first electrodes 17A and the first busbar electrode 18A define a first comb-shaped electrode (first IDT electrode), which is a first functional electrode 14A. The second electrodes 17B and the second busbar electrode 18B define a second comb-shaped electrode (second IDT electrode), which is a second functional electrode 14B. The first functional electrode 14A and the second functional electrode 14B face each other in an intersecting direction (plane direction in FIG. 5), which is a direction intersecting with the stacking direction of the support substrate 11 and the piezoelectric layer 12.

As viewed in the stacking direction of the support substrate 11 and the piezoelectric layer 12, at least a portion of the first functional electrode 14A and at least a portion of the second functional electrode 14B overlap the first hollow portion 13.

The functional electrode 14 is made of a suitable metal or alloy, such as, for example, Al or an AlCu alloy. For example, the functional electrode 14 has a structure in which an Al layer is stacked on a Ti layer. A contact layer made of a material other than Ti may be used.

The wiring electrode 16 includes a first wiring electrode 16A and a second wiring electrode 16B, for example. The first wiring electrode 16A is connected to the first comb-shaped electrode, which is the first functional electrode 14A. The second wiring electrode 16B is connected to the second comb-shaped electrode, which is the second functional electrode 14B.

The wiring electrode 16 is made of a suitable metal or alloy, such as, for example, Al or an AlCu alloy. For example, the wiring electrode 16 has a structure in which an Al layer is stacked on a Ti layer. A contact layer made of a material other than Ti may be used.

The acoustic wave device 10A also includes a first cover section 21 separated from the first main surface 12a of the piezoelectric layer 12 with a space therebetween. A first support section 22 is provided between the first cover section 21 and the piezoelectric layer 12 or the support substrate 11. A second hollow portion 23 is provided between the first cover section 21 and the functional electrode 14.

As viewed in the stacking direction of the support substrate 11 and the piezoelectric layer 12, the first cover section 21 overlaps the first and second functional electrodes 14A and 14B and the first and second wiring electrodes 16A and 16B.

The first cover section 21 is made of Si, for example. The material for the first cover section 21 may be the same as that of the support substrate 11 or may be different from that of the support substrate 11.

The first support section 22 is defined by a ring electrode which surrounds the functional electrode 14 and the wiring electrode 16, for example. In this case, the first support section 22 includes a multilayer body made of a conductive film, a seal electrode stacked on the conductive film, and a bonding electrode stacked on the seal electrode in order from the side of the support substrate 11, for example. The first cover section 21 and the piezoelectric layer 12 are bonded to each other via the ring electrode. The first support section 22 may include a multilayer body without a conductive film, which is defined by a seal electrode and a bonding electrode stacked on the seal electrode in order from the side of the support substrate 11.

The conductive film is made of the same material as that of the functional electrode 14, for example. The seal electrode includes gold (Au), for example. The bonding electrode includes Au, for example.

The acoustic wave device 10A may also include a second cover section 31 which closes the first hollow portion 13. A second support section 32 is provided between the second cover section 31 and the support substrate 11.

The second cover section 31 is made of Si, for example. The material for the second cover section 31 may be the same as that of the support substrate 11 or may be different from that of the support substrate 11. The material for the second cover section 31 may be the same as that of the first cover section 21 or may be different from that of the first cover section 21.

The second support section 32 is defined by a ring electrode which surrounds the first hollow portion 13, for example. In this case, the second support section 32 includes a multilayer body including a seal electrode and a bonding electrode stacked on the seal electrode in order from the side of the support substrate 11, for example. The second cover section 31 and the support substrate 11 are bonded to each other via the ring electrode.

A frequency adjusting film 33 may be provided on the surface of the piezoelectric layer 12 on the side adjacent to the second cover section 31 so as to overlap the first hollow portion 13.

The frequency adjusting film 33 is made of a material, such as SiOₓ or SiₓN_{y}, or a multilayer body thereof, for example. In this case, the frequency adjusting film 33 may be made of a material, such as SiO₂ or Si₃N₄, or a multilayer body thereof, for example.

Preferably, the acoustic wave device 10A also includes a terminal electrode 35 and a pad electrode 36. The terminal electrode 35 passes through the second cover section 31 and is connected to an extended electrode 34 provided on the main surface of the support substrate 11 on the side adjacent to the second cover section 31. The pad electrode 36 is connected to the terminal electrode 35. The extended electrode 34 is electrically connected to a wiring electrode (such as a feeding electrode 19) disposed on the main surface of the support substrate 11 on the side adjacent to the first cover section 21. A seed layer electrode 37 may be provided on the bottom surfaces of the terminal electrode 35 and the pad electrode 36.

The terminal electrode 35 includes a Cu layer, such as a Cu plating layer, for example. The pad electrode 36 includes a Cu layer, such as a Cu plating layer, a Ni layer, such as a Ni plating layer, and an Au layer, such as an Au plating layer, in order from the side of the terminal electrode 35, for example. The seed layer electrode 37 includes a Ti layer and a Cu layer in order from the side of the first cover section 21, for example.

The terminal electrode 35 and the pad electrode 36 define an under bump metal (UBM) layer. A bump, such as, for example, a BGA (Ball Grid Array), may be provided on the pad electrode 36 defining the UBM layer.

The main surface of the first cover section 21 on the side adjacent to the piezoelectric layer 12 and that of the first cover section 12 opposite the side adjacent to the piezoelectric layer 12 may be covered with an insulating film 25 (hereinafter may also be referred to as a dielectric film 25). Similarly, the main surface of the second cover section 31 on the side adjacent to the support substrate 11 and the second main surface of the second cover section 31 opposite the side adjacent to the support substrate 11 may be covered with an insulating film 25.

The insulating film 25 is made of SiOₓ, for example. In this case, the insulating film 25 may be made of, for example, SiO₂.

The surface of the functional electrode 14 may be covered with a protection film 26.

The protection film 26 is made of SiOₓ, for example. In this case, the protection film 26 may be made of, for example, SiO₂.

As illustrated in FIGS. 4 and 5, a third wiring electrode 16C is disposed above the first wiring electrode 16A connected to the first functional electrode 14A, while a fourth wiring electrode 16D is disposed above the second wiring electrode 16B connected to the second functional electrode 14B.

As illustrated in FIGS. 4 and 6, a first relay electrode 24A is disposed above the third wiring electrode 16C, while a second wiring electrode 24B is disposed above the fourth wiring electrode 16D.

The first relay electrode 24A is disposed, not only above the third wiring electrode 16C, but also on the main surface of the first cover section 21 on the side adjacent to the piezoelectric layer 12. The first relay electrode 24A is electrically connected to the first functional electrode 14A.

The second relay electrode 24B is disposed, not only above the fourth wiring electrode 16D, but also on the main surface of the first cover section 21 on the side adjacent to the piezoelectric layer 12. The second relay electrode 24B is electrically connected to the second functional electrode 14B.

As viewed in the stacking direction of the support substrate 11 and the piezoelectric layer 12, at least a portion of the first relay electrode 24A overlaps at least one of the first functional electrode 14A and the second functional electrode 14B. Similarly, as viewed in the stacking direction of the support substrate 11 and the piezoelectric layer 12, at least a portion of the second relay electrode 24B overlaps at least one of the first functional electrode 14A and the second functional electrode 14B. With this configuration, a capacitor can be provided between the functional electrode 14 and the relay electrode 24, thus adding capacitance and improving the characteristics of the acoustic wave device 10A without increasing the size thereof. As viewed in the stacking direction of the support substrate 11 and the piezoelectric layer 12, at least one of the first relay electrode 24A and the second relay electrode 24B may overlap the functional electrode 14.

A dielectric film 25 may be provided between the main surface of the first cover section 21 on the side adjacent to the piezoelectric layer 12 and at least one of the first relay electrode 24A and the second relay electrode 24B.

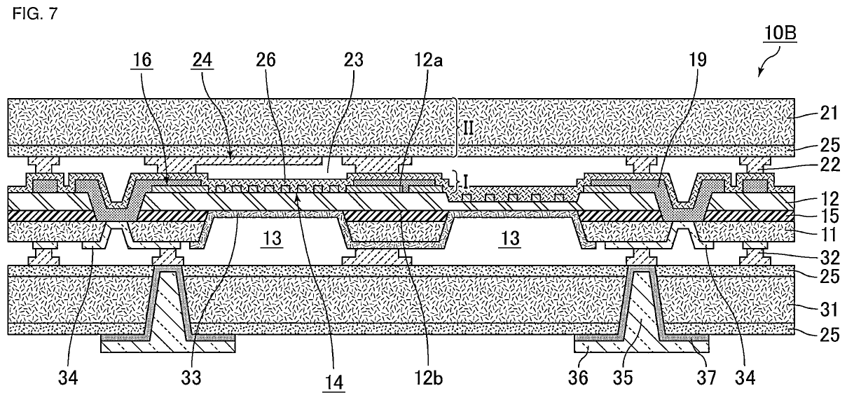

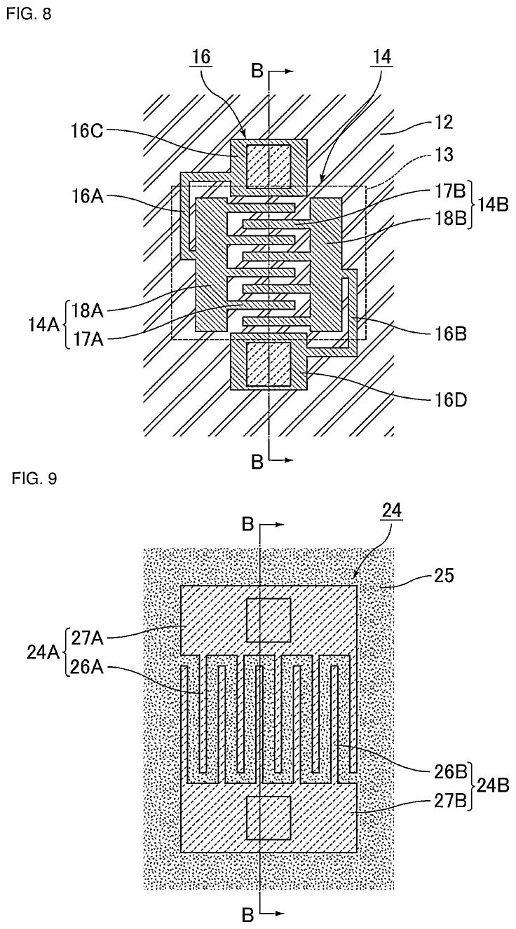

FIG. 7 is a sectional view schematically illustrating an example of an acoustic wave device according to a second preferred embodiment of the present invention. FIG. 8 is a plan view of a piezoelectric layer and elements thereon in the region indicated by I in FIG. 7. FIG. 9 is a plan view of a first cover section and elements thereon in the region indicated by II in FIG. 7. A cross section taken along line B-B in each of FIGS. 8 and 9 is shown in FIG. 7.

An acoustic wave device 10B according to the second preferred embodiment shown in FIGS. 7, 8, and 9 is different from the acoustic wave device 10A according to the first preferred embodiment in the configurations of the first and second relay electrodes 24A and 24B.

In the acoustic wave device 10B of the second preferred embodiment, the first relay electrode 24A and the second relay electrode 24B face each other in the intersecting direction (plane direction in FIG. 9) on the main surface of the first cover section 21 on the side adjacent to the piezoelectric layer 12. With this configuration, the relay electrodes 24 can face each other on the first cover section 21, thus further increasing the capacitance to be added.

The first relay electrode 24A includes, for example, a plurality of third electrodes 26A (may also referred to as third electrode fingers 26A) and a third busbar electrode 27A to which the third electrodes 26A are connected. The first relay electrode 24A defines a comb-shaped electrode, as in the first comb-shaped electrode.

The second relay electrode 24B includes, for example, a plurality of fourth electrodes 26B (may also be referred to as fourth electrode fingers 26B) and a fourth busbar electrode 27B to which the fourth electrodes 26B are connected. The second relay electrode 24B defines a comb-shaped electrode, as in the second comb-shaped electrode.

In FIG. 9, the third electrodes 26A and the fourth electrodes 26B extend in the top-bottom direction and the third busbar electrode 27A and the fourth busbar electrode 27B extend in the left-right direction, so that a pair of adjacent third electrode 26A and fourth electrode 26B face each other in the left-right direction. Alternatively, for example, the third electrodes 26A and the fourth electrodes 26B may extend in the left-right direction and the third busbar electrode 27A and the fourth busbar electrode 27B may extend in the top-bottom direction, so that a pair of adjacent third electrode 26A and fourth electrode 26B may face each other in the top-bottom direction.

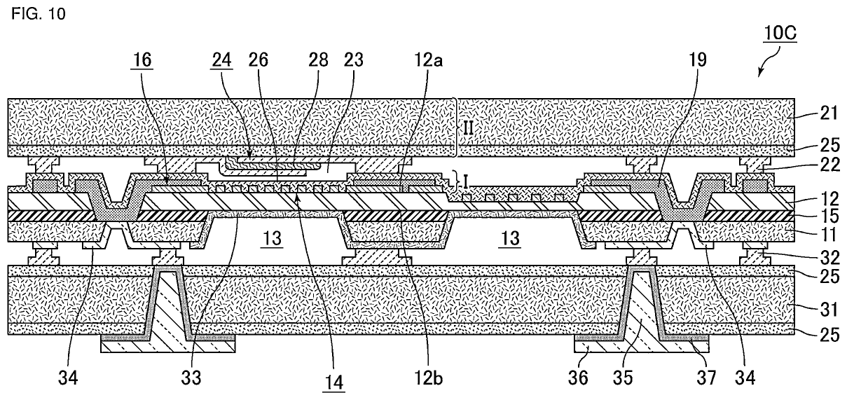

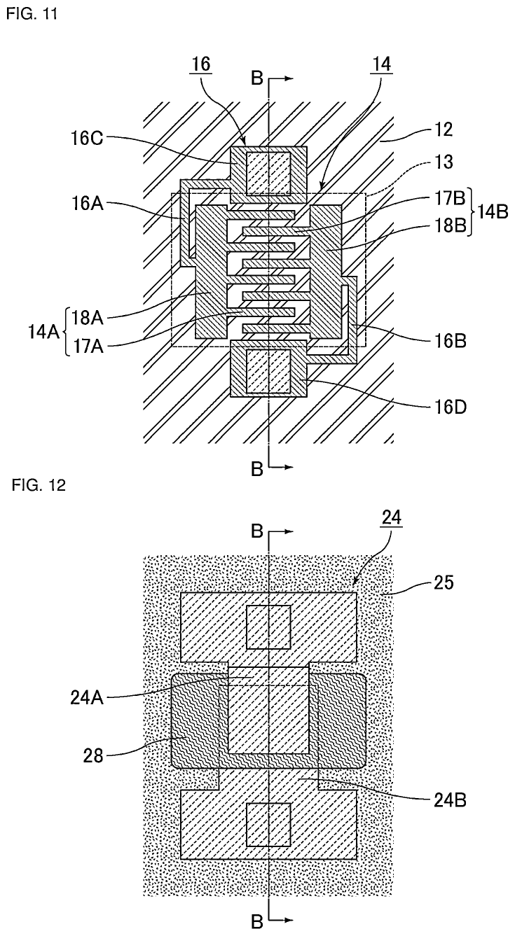

FIG. 10 is a sectional view schematically illustrating an example of an acoustic wave device according to a third preferred embodiment of the present invention. FIG. 11 is a plan view of a piezoelectric layer and elements thereon in the region indicated by I in FIG. 10. FIG. 12 is a plan view of a first cover section and elements thereon in the region indicated by II in FIG. 10. A cross section taken along line B-B in each of FIGS. 11 and 12 is shown in FIG. 10.

An acoustic wave device 10C according to the third preferred embodiment shown in FIGS. 10, 11, and 12 is different from the acoustic wave device 10A according to the first preferred embodiment and the acoustic wave device 10B according to the second preferred embodiment in the configurations of the first and second relay electrodes 24A and 24B.

In the acoustic wave device 10C of the third preferred embodiment, the first relay electrode 24A and the second relay electrode 24B face each other in the stacking direction of the support substrate 11 and the piezoelectric layer 12. With this configuration, the relay electrodes 24 can face each other on the first cover section 21, thus further increasing the capacitance to be added.

As illustrated in FIGS. 10 and 12, a dielectric film 28 is preferably provided between the first relay electrode 24A and the second relay electrode 24B. More specifically, it is preferable that the dielectric film 28 is provided on the first cover section 21 and that the first relay electrode 24A and the second relay electrode 24B face each other with the dielectric film 28 interposed therebetween in the stacking direction of the support substrate 11 and the piezoelectric layer 12. In this case, although more steps are required due to the addition of a step of providing the dielectric film 28, capacitance can be added even if the precision of the pattern of the relay electrode 24 is low. Moreover, selecting a dielectric film 28 with a high dielectric constant can reduce the area of the pattern of the relay electrode 24.

A dielectric film 25 may be provided between the main surface of the first cover section 21 on the side adjacent to the piezoelectric layer 12 and at least one of the first relay electrode 24A and the second relay electrode 24B.

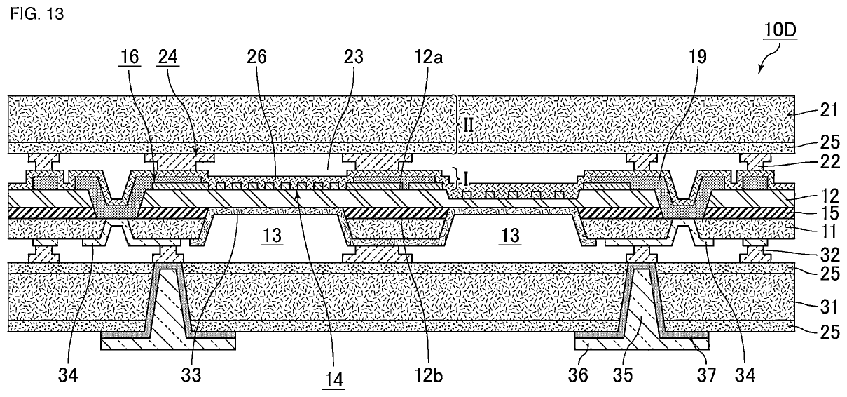

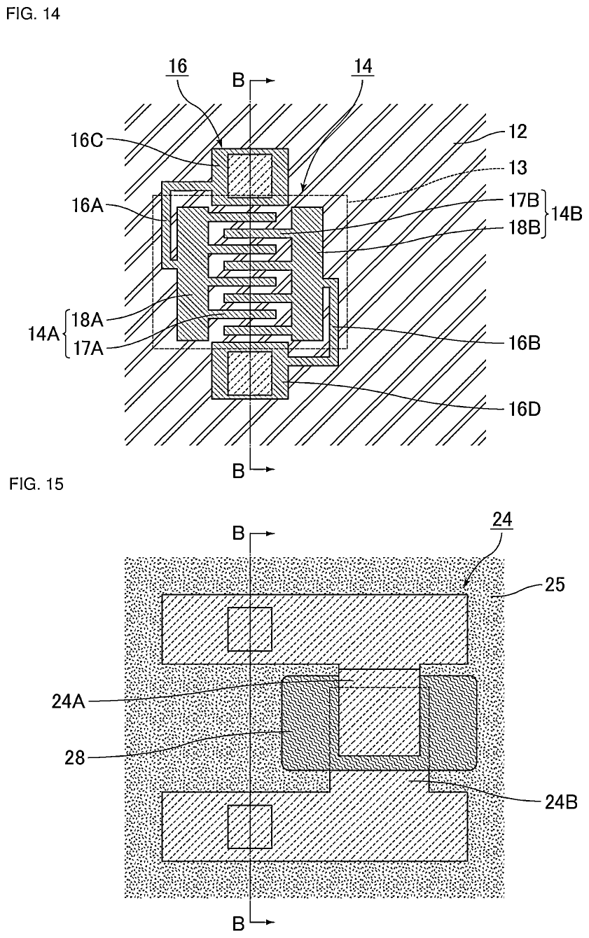

FIG. 13 is a sectional view schematically illustrating an example of an acoustic wave device according to a fourth preferred embodiment of the present invention. FIG. 14 is a plan view of a piezoelectric layer and elements thereon in the region indicated by I in FIG. 13. FIG. 15 is a plan view of a first cover section and elements thereon in the region indicated by II in FIG. 13. A cross section taken along line B-B in each of FIGS. 14 and 15 is shown in FIG. 13.

In an acoustic wave device 10D according to the fourth preferred embodiment shown in FIGS. 13, 14, and 15, the relay electrode 24 does not overlap the functional electrode 14 as viewed in the stacking direction of the support substrate 11 and the piezoelectric layer 12.

As in the acoustic wave device 10B of the second preferred embodiment or the acoustic wave device 10C of the third preferred embodiment, if the first relay electrode 24A and the second relay electrode 24B face each other, it is not necessary that the first and second relay electrodes 24A and 24B overlaps the functional electrode 14 as viewed in the stacking direction of the support substrate 11 and the piezoelectric layer 12. For example, as illustrated in FIGS. 13, 14, and 15, the first relay electrode 24A and the second relay electrode 24B may be displaced to a position at which they do not overlap the functional electrode 14, and at this position, they may face each other. In this case, too, a capacitor can be provided by the first relay electrode 24A and the second relay electrode 24B, thus adding capacitance to a resonator in parallel.

In FIG. 15, the first relay electrode 24A and the second relay electrode 24B face each other in the stacking direction of the support substrate 11 and the piezoelectric layer 12. Alternatively, as illustrated in FIG. 9, the first relay electrode 24A and the second relay electrode 24B may face each other in the intersecting direction on the main surface of the first cover section 21 on the side adjacent to the piezoelectric layer 12.

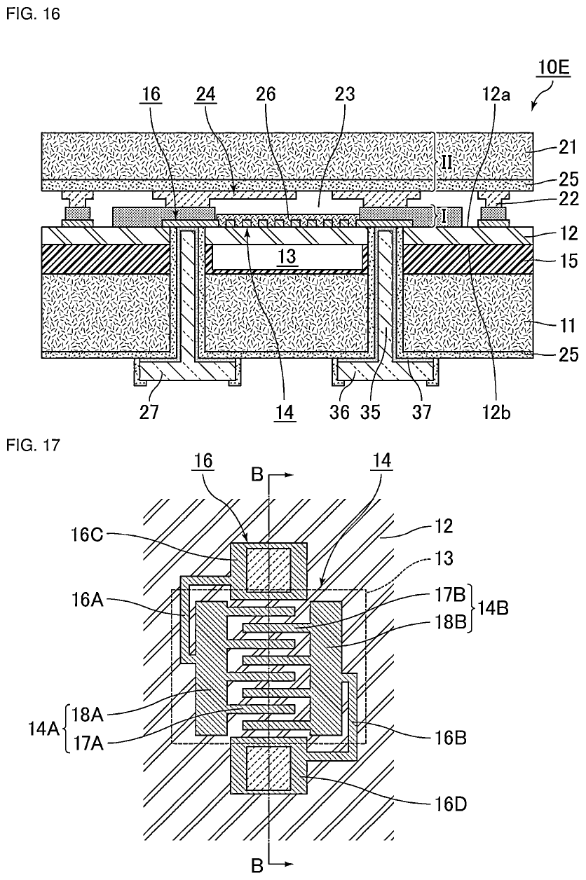

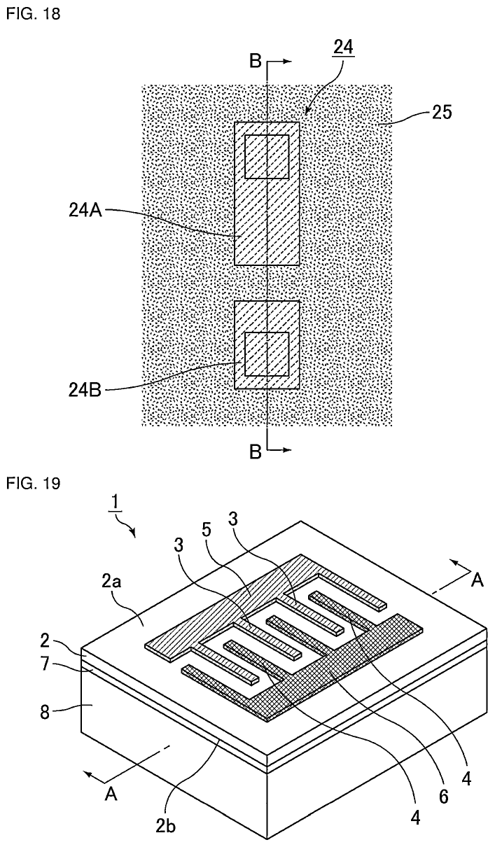

FIG. 16 is a sectional view schematically illustrating an example of an acoustic wave device according to a fifth preferred embodiment of the present invention. FIG. 17 is a plan view of a piezoelectric layer and elements thereon in the region indicated by I in FIG. 16. FIG. 18 is a plan view of a first cover section and elements thereon in the region indicated by II in FIG. 16. A cross section taken along line B-B in each of FIGS. 17 and 18 is shown in FIG. 16.

An acoustic wave device 10E according to the fifth preferred embodiment shown in FIGS. 16, 17, and 18 is different from the first through fourth preferred embodiments in that the first hollow portion 13 does not pass through the support substrate 11 and the intermediate layer 15. In this case, for example, the UBM layer defined by the terminal electrode 35 and the pad electrode 36 passes through the support substrate 11 and is electrically connected to the wiring electrode 16 on the piezoelectric layer 12.

The thickness shear mode and a Lamb wave will be explained below in detail. An explanation will be provided, assuming that the functional electrode is an IDT electrode by way of example. In the following example, a support member corresponds to the support substrate, and an insulating layer corresponds to the intermediate layer.

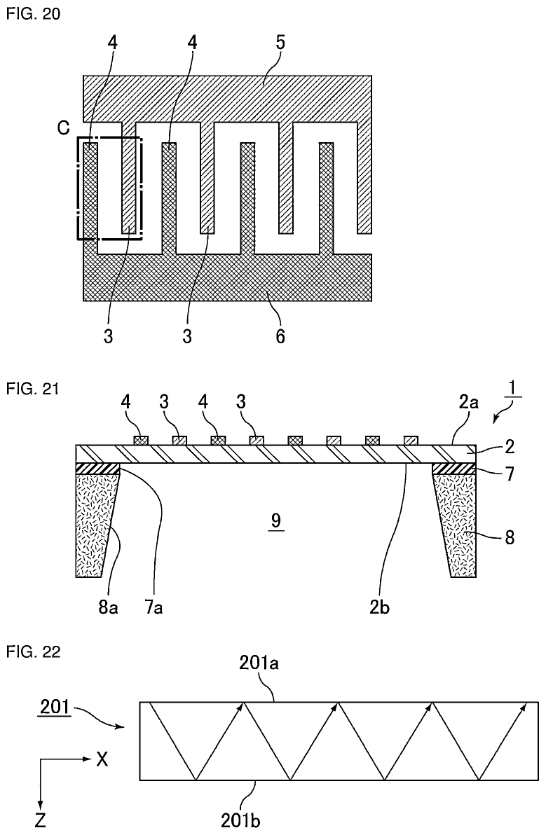

FIG. 19 is a schematic perspective view illustrating the outer appearance of an example of an acoustic wave device utilizing a bulk wave of the thickness shear mode. FIG. 20 is a plan view illustrating the electrode structure on a piezoelectric layer of the acoustic wave device shown in FIG. 19. FIG. 21 is a sectional view of a portion along line A-A in FIG. 19.

An acoustic wave device 1 includes a piezoelectric layer 2 made of LiNbO₃, for example. The piezoelectric layer 2 may alternatively be made of LiTaO₃, for example. The cut angle of LiNbO₃ or LiTaO₃ is Z-cut, for example, but may be rotated Y-cut or X-cut. Preferably, the cut-angle of LiNbO₃ or LiTaO₃ is, for example, a propagation direction of Y-propagation of about ±30° and X-propagation of about ±30°. Although the thickness of the piezoelectric layer 2 is not restricted to a particular thickness, it is preferably, for example, about 50 nm to about 1000 nm to effectively excite the thickness shear mode. The piezoelectric layer 2 includes first and second main surfaces 2a and 2b opposing each other. On the first main surface 2a, electrodes 3 and 4 are disposed. The electrode 3 is an example of a “first electrode”, while the electrode 4 is an example of a “second electrode”. In FIGS. 19 and 20, the plurality of electrodes 3 are a plurality of first electrode fingers connected to a first busbar 5, while the plurality of electrodes 4 are a plurality of second electrode fingers connected to a second busbar 6. The plurality of electrodes 3 and the plurality of electrodes 4 are interdigitated with each other. The electrodes 3 and 4 have a rectangular or substantially rectangular shape and includes a longitudinal direction. An electrode 3 and an adjacent electrode 4 face each other in a direction perpendicular or substantially perpendicular to this longitudinal direction. The plurality of electrodes 3 and 4 and the first and second busbars 5 and 6 define an IDT (Interdigital Transducer) electrode. The longitudinal direction of the electrodes 3 and 4 and the direction perpendicular or substantially perpendicular to the longitudinal direction of the electrodes 3 and 4 are both directions intersecting with the thickness direction of the piezoelectric layer 2. It can thus be said that an electrode 3 and an adjacent electrode 4 face each other in a direction intersecting with the thickness direction of the piezoelectric layer 2. The electrodes 3 and 4 may extend in a direction perpendicular or substantially perpendicular to the longitudinal direction of the electrodes 3 and 4 shown in FIGS. 19 and 20. That is, the electrodes 3 and 4 may extend in the extending direction of the first busbar 5 and the second busbar 6 shown in FIGS. 19 and 20. In this case, the first busbar 5 and the second busbar 6 extend in the extending direction of the electrodes 3 and 4 shown in FIGS. 19 and 20. Multiple pairs of electrodes 3 and electrodes 4, each pair including an electrode 3, which is connected to one potential, and an electrode 4, which is connected to the other potential, adjacent to each other, are arranged in the direction perpendicular or substantially perpendicular to the longitudinal direction of the electrodes 3 and 4. “Electrodes 3 and 4 adjacent to each other” refers to, not that the electrodes 3 and 4 are disposed to directly contact each other, but that the electrodes 3 and 4 are disposed with a space therebetween. When electrodes 3 and 4 are adjacent to each other, an electrode connected to a hot electrode and an electrode connected to a ground electrode, including the other electrodes 3 and 4, are not disposed between the adjacent electrodes 3 and 4. The number of pairs of the electrodes 3 and 4 is not necessarily an integral number and may be 1.5 or 2.5, for example. The center-to-center distance, that is, the pitch, between the electrodes 3 and 4 is preferably, for example, about 1 μm to about 10 μm. The center-to-center distance between the electrodes 3 and 4 is a distance from the center of the width of the electrode 3 in the direction perpendicular or substantially perpendicular to the longitudinal direction of the electrode 3 to that of the electrode 4 in the direction perpendicular or substantially perpendicular to the longitudinal direction of the electrode 4. When at least one of the number of electrodes 3 and the number of electrodes 4 is plural (when 1.5 or more pairs of electrodes 3 and 4, each pair being formed by an electrode 3 and an electrode 4, are provided), the center-to-center distance between electrodes 3 and 4 is the average value of that between adjacent electrodes 3 and 4 of the 1.5 or more pairs. The width of each of the electrodes 3 and 4, that is, the dimension in the facing direction of the electrodes 3 and 4, is preferably, for example, about 150 nm to about 1000 nm.

In the present preferred embodiment, when a Z-cut piezoelectric layer is used, the direction perpendicular or substantially perpendicular to the longitudinal direction of the electrodes 3 and 4 is a direction perpendicular or substantially perpendicular to the polarization direction of the piezoelectric layer 2. However, this is not the case if a piezoelectric layer of another cut angle is used as the piezoelectric layer 2. “Being perpendicular” does not necessarily mean being exactly perpendicular, but may mean being substantially perpendicular. For example, the angle between the direction perpendicular to the longitudinal direction of the electrodes 3 and 4 and the polarization direction may be in a range of, for example, about ±10°.

A support member 8 is stacked on the second main surface 2b of the piezoelectric layer 2 with an insulating layer 7 interposed therebetween. The insulating layer 7 and the support member 8 have a frame shape and include cavities 7a and 8a, respectively, as shown in FIG. 21. With this structure, a hollow portion 9 is provided. The hollow portion 9 is provided not to interfere with the vibration of an excitation region C (see FIG. 20) of the piezoelectric layer 2. Thus, the support member 8 is stacked on the second main surface 2b with the insulating layer 7 therebetween and is located at a position at which the support member 8 does not overlap a region where at least one pair of electrodes 3 and 4 are disposed. The insulating layer 7 may be omitted. The support member 8 can thus be stacked directly or indirectly on the second main surface 2b of the piezoelectric layer 2.

The insulating layer 7 is made of silicon oxide, for example. Instead of silicon oxide, another suitable insulating material, such as, for example, silicon oxynitride or alumina, may be used. The support member 8 is made of, for example, Si. The plane orientation of the Si plane on the side of the piezoelectric layer 2 may be (100), (110), or (111). Preferably, high-resistivity Si, such as Si having a resistivity of, for example, about 4 kΩ or higher, is used. A suitable insulating material or semiconductor material may be used for the support member 8. Examples of the material for the support member 8 are piezoelectric materials, such as aluminum oxide, lithium tantalate, lithium niobate, and quartz, various ceramic materials, such as alumina, magnesia, sapphire, silicon nitride, aluminum nitride, silicon carbide, zirconia, cordierite, mullite, steatite, and forsterite, dielectric materials, such as diamond and glass, and semiconductor materials, such as gallium nitride.

The plurality of electrodes 3 and 4 and first and second busbars 5 and 6 are made of a suitable metal or alloy, such as Al or an AlCu alloy, for example. In the present preferred embodiment, the electrodes 3 and 4 and the first and second busbars 5 and 6 have a structure including, for example, an Al film is stacked on a Ti film. A contact layer made of a material other than Ti may be used.

To drive the acoustic wave device 1, an AC voltage is applied to between the plurality of electrodes 3 and the plurality of electrodes 4. More specifically, an AC voltage is applied between the first busbar 5 and the second busbar 6. With the application of the AC voltage, resonance characteristics based on a bulk wave of the thickness shear mode excited in the piezoelectric layer 2 can be provided. In the acoustic wave device 1, d/p is set to, for example, about 0.5 or smaller, where d is the thickness of the piezoelectric layer 2 and p is the center-to-center distance between adjacent electrodes 3 and 4 forming one of multiple pairs of electrodes 3 and 4. This can effectively excite a bulk wave of the thickness shear mode and obtain high resonance characteristics. More preferably, d/p is, for example, about 0.24 or smaller, in which case, even higher resonance characteristics can be obtained. As in the present preferred embodiment, when at least one of the number of electrodes 3 and the number of electrodes 4 is plural, that is, when 1.5 or more pairs of electrodes 3 and 4, each pair being formed by an electrode 3 and an electrode 4, are provided, the center-to-center distance p between adjacent electrodes 3 and 4 is the average distance between adjacent electrodes 3 and 4 of the individual pairs.

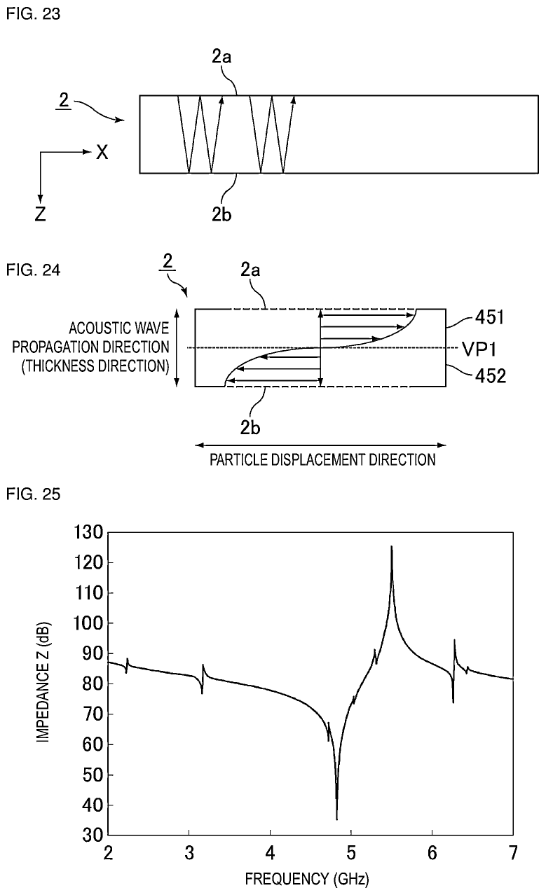

The acoustic wave device 1 of the present preferred embodiment is configured as described above. Even if the number of pairs of the electrodes 3 and 4 is reduced to miniaturize the acoustic wave device 1, the Q factor is unlikely to be decreased. This is because the acoustic wave device 1 is a resonator which does not require reflectors on both sides and only a small propagation loss occurs. The reason why the acoustic wave device 1 does not require reflectors is that a bulk wave of the thickness shear mode is used. The difference between a Lamb wave used in a known acoustic wave device and a bulk wave of the thickness shear mode will be explained below with reference to FIGS. 22 and 23.

FIG. 22 is a schematic elevational cross-sectional view for explaining a Lamb wave propagating through a piezoelectric film of an acoustic wave device. As illustrated in FIG. 22, in an acoustic wave device, such as that disclosed in Japanese Unexamined Patent Application Publication No. 2012-257019, a wave propagates through a piezoelectric film 201, as indicated by the arrows. A first main surface 201a and a second main surface 201b of the piezoelectric film 201 oppose each other and the thickness direction in which the first main surface 201a and the second main surface 201b are linked with each other is the Z direction. The X direction is a direction in which the electrode fingers of an IDT electrode are arranged. As illustrated in FIG. 22, a Lamb wave propagates in the X direction. Because of the characteristics of a Lamb wave, the Lamb wave propagates in the X direction although the piezoelectric film 201 is entirely vibrated, and thus, reflectors are disposed on both sides to obtain resonance characteristics. Because of these characteristics, a propagation loss occurs in the wave. If the number of pairs of electrode fingers is reduced to miniaturize the acoustic wave device, the Q factor is decreased.

FIG. 23 is a schematic elevational cross-sectional view for explaining a bulk wave of the thickness shear mode propagating through a piezoelectric layer of an acoustic wave device. As illustrated in FIG. 23, in the acoustic wave device 1 of the present preferred embodiment, since the vibration displacement direction is the thickness shear direction, a wave propagates and resonates substantially in a direction in which the first main surface 2a and the second main surface 2b are linked with each other, namely, substantially in the Z direction. That is, the X-direction components of the wave are much smaller than the Z-direction components. The resonance characteristics are obtained as a result of the wave propagating in the Z direction, and thus, the acoustic wave device 1 does not require reflectors. Thus, a propagation loss, which would be caused by the propagation of a wave to reflectors, does not occur. Even if the number of pairs of the electrodes 3 and 4 is reduced to miniaturize the acoustic wave device 1, the Q factor is unlikely to be decreased.

FIG. 24 is a diagram illustrating the amplitude direction of a bulk wave of the thickness shear mode. Regarding the amplitude direction of a bulk wave of the thickness shear mode, as shown in FIG. 24, the amplitude direction in a first region 451 included in the excitation region C of the piezoelectric layer 2, and that in a second region 452 included in the excitation region C, become opposite. In FIG. 24, a bulk wave generated when a voltage is applied between the electrodes 3 and 4 so that the potential of the electrode 4 becomes higher than that of the electrode 3 is schematically illustrated. The first region 451, which is a portion of the excitation region C, is a region between a virtual plane VP1 and the first main surface 2a. The virtual plane VP1 is perpendicular or substantially perpendicular to the thickness direction of the piezoelectric layer 2 and divides the piezoelectric layer 2 into two regions. The second region 452, which is a portion of the excitation region C, is a region between the virtual plane VP1 and the second main surface 2b.

As discussed above, in the acoustic wave device 1, at least one pair of electrodes 3 and 4 is provided. Since a wave does not propagate through the piezoelectric layer 2 of the acoustic wave device 1 in the X direction, it is not necessary that a plurality of pairs of electrodes 3 and 4 are provided. That is, at least one pair of electrodes is sufficient.

In one example, the electrode 3 is an electrode connected to a hot potential, while the electrode 4 is an electrode connected to a ground potential. Conversely, the electrode 3 may be connected to a ground potential, while the electrode 4 may be connected to a hot potential. In the present preferred embodiment, as described above, at least one pair of electrodes is connected to a hot potential and a ground potential, and more specifically, one electrode defining this pair is an electrode connected to a hot potential, and the other electrode is an electrode connected to a ground potential. No floating electrode is provided.

FIG. 25 is a graph illustrating an example of the resonance characteristics of the acoustic wave device shown in FIG. 19. The design parameters of the acoustic wave device 1 that has obtained the resonance characteristics shown in FIG. 25 are as follows.

The piezoelectric layer 2 is LiNbO₃ having the Euler angles of (0°, 0°, 90°) and a thickness of about 400 nm.

The length of a region where the electrodes 3 and 4 overlap each other as viewed in a direction perpendicular to the longitudinal direction of the electrodes 3 and 4, that is, the length of the excitation region C is about 40 μm. The number of pairs of electrodes 3 and 4 is 21. The center-to-center distance between electrodes is 3 μm. The width of the electrodes 3 and 4 is about 500 nm. d/p is about 0.133.

The insulating layer 7 is a silicon oxide film having a thickness of about 1 μm.

The support member 8 is a Si substrate.

The length of the excitation region C is a dimension of the excitation region in the longitudinal direction of the electrodes 3 and 4.

In the acoustic wave device 1, the electrode-to-electrode distance of an electrode pair defined by electrodes 3 and 4 was set to all be equal or substantially equal among plural pairs. That is, the electrodes 3 and 4 were disposed at equal or substantially equal pitches.

As is seen from FIG. 25, despite that no reflectors are provided, high resonance characteristics having a fractional bandwidth of, for example, about 12.5% are obtained.

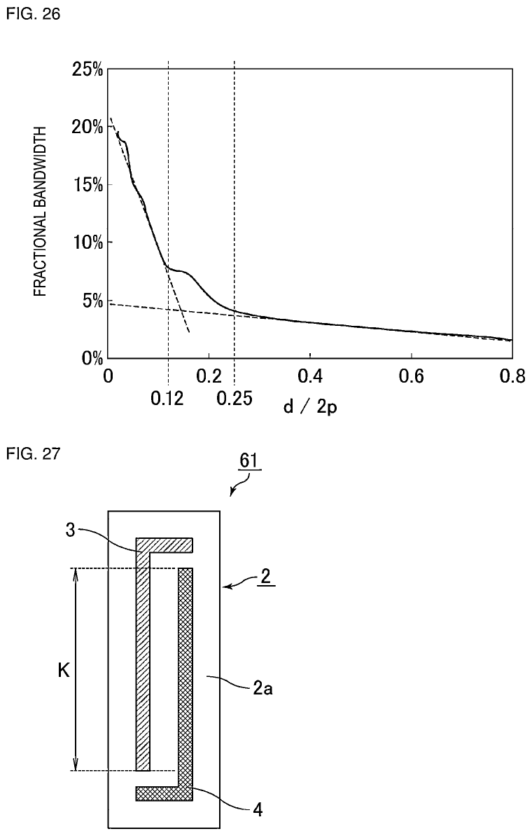

In the present preferred embodiment, as stated above, d/p is, for example, about 0.5 or smaller, and more preferably, d/p is about 0.24 or smaller, where d is the thickness of the piezoelectric layer 2 and p is the center-to-center distance between the electrodes 3 and 4. This will be explained below with reference to FIG. 26.

Plural acoustic wave devices were made in a manner similar to the acoustic wave device which has obtained the resonance characteristics shown in FIG. 25, except that d/2p was varied among these plural acoustic wave devices. FIG. 26 is a graph illustrating the relationship between d/2p, where d is the thickness of the piezoelectric layer and p is the center-to-center distance between adjacent electrodes, and the fractional bandwidth of each of the plural acoustic wave devices as resonators.

As is seen from FIG. 26, when, for example, d/2p exceeds about 0.25, that is, d/p>about 0.5, the fractional bandwidth remains less than about 5% even if d/p is changed. In contrast, when, for example d/2p≤about 0.25, that is, when d/p≤about 0.5, the fractional bandwidth can be improved to about 5% or higher as long as d/p is changed in this range. It is thus possible to provide a resonator having a high coupling coefficient. When d/2p is, for example, about 0.12 or smaller, that is, when d/p is about 0.24 or smaller, the fractional bandwidth can be improved to about 7% or higher. Additionally, if d/p is adjusted in this range, a resonator having an even higher fractional bandwidth can be obtained. It is thus possible to provide a resonator having an even higher coupling coefficient. Therefore, it has been validated that, as a result of setting d/p to, for example, about 0.5 or smaller, a resonator having a high coupling coefficient which utilizes a bulk wave of the thickness shear mode can be formed.

As stated above, at least one pair of electrodes may include only one pair of electrodes. If one pair of electrodes is provided, the above-described center-to-center distance p is the center-to-center distance between adjacent electrodes 3 and 4. If 1.5 or more pairs of electrodes are provided, the center-to-center distance p is the average distance between adjacent electrodes 3 and 4 of the individual pairs.

Regarding the thickness d of the piezoelectric layer, if the piezoelectric layer 2 has variations in the thickness, the averaged thickness value may be used.

FIG. 27 is a plan view illustrating another example of an acoustic wave device utilizing a bulk wave of the thickness shear mode.

In an acoustic wave device 61, a pair of electrodes, that is, a pair of electrodes 3 and 4, is provided on the first main surface 2a of the piezoelectric layer 2. K in FIG. 27 indicates the intersecting width. As stated above, in the acoustic wave device of the present preferred embodiment, only one pair of electrodes may be provided. Even in this case, a bulk wave of the thickness shear mode can be effectively excited if, for example, d/p is about 0.5 or smaller.

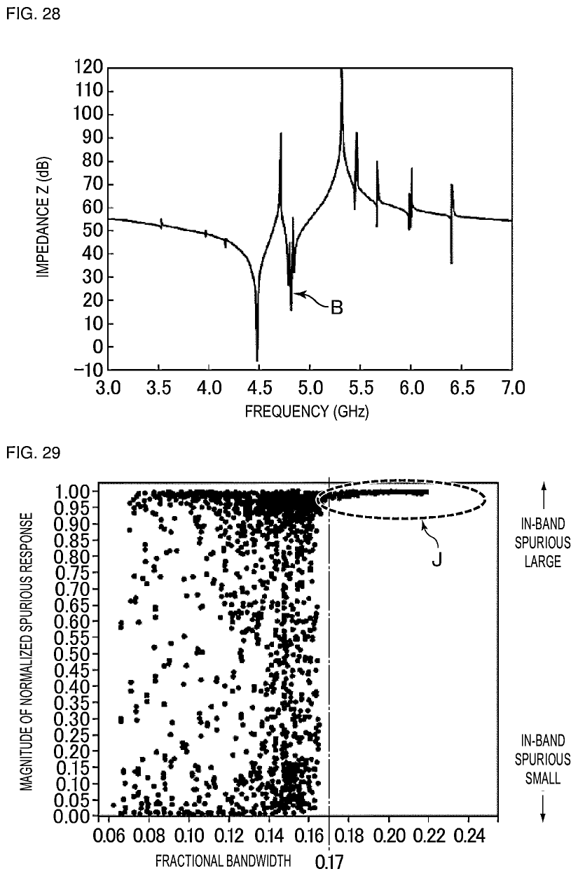

In the acoustic wave device of the present preferred embodiment, the metallization ratio MR of any one pair of adjacent electrodes 3 and 4 to the excitation region where these electrodes 3 and 4 overlap each other as seen in the facing direction of the electrodes preferably satisfies, for example, MR about 1.75(d/p)+0.075. In this case, spurious responses can be effectively reduced. This will be explained below with reference to FIGS. 28 and 29.

FIG. 28 is a reference diagram illustrating an example of the resonance characteristics of the acoustic wave device shown in FIG. 19. The spurious response indicated by the arrow B is observed between the resonant frequency and the anti-resonant frequency. d/p was set to, for example, about 0.08, and the Euler angles of LiNbO₃ were set to (0°, 0°, 90°). The metallization ratio MR was set to, for example, about 0.35.

The metallization ratio MR will be explained below with reference to FIG. 20. In the electrode structure in FIG. 20, a pair of electrodes 3 and 4 is shown and described, and it is assumed that only this pair is provided. In this case, the portion surrounded by the long dashed dotted lines C is the excitation region. The excitation region is a region where the electrode 3 overlaps the electrode 4, a region where the electrode 4 overlaps the electrode 3, and a region where the electrodes 3 and 4 overlap each other in the region between the electrodes 3 and 4, when the electrodes 3 and 4 are seen in the direction perpendicular to the longitudinal direction thereof, that is, in the facing direction of the electrodes 3 and 4. The area of the electrodes 3 and 4 within the excitation region C to the area of the excitation region is the metallization ratio MR. That is, the metallization ratio MR is a ratio of the area of a metallized portion to the area of the excitation region.

If a plurality of pairs of electrodes are provided, the ratio of the area of the metallized portions included in the total excitation region to the total area of the excitation region is used as the metallization ratio MR.

Many acoustic wave resonators were provided based on the present preferred embodiment. FIG. 29 is a diagram illustrating the relationship between the fractional bandwidth and the amount of phase shift of the impedance of a spurious response normalized at about 180 degrees. The amount of phase shift represents the magnitude of a spurious response. The fractional bandwidth was adjusted by variously changing the film thickness of the piezoelectric layer and the dimensions of electrodes. The results shown in FIG. 29 are obtained when a piezoelectric layer made of, for example, Z-cut LiNbO₃ was used. Similar results are also obtained if a piezoelectric layer having another cut-angle is used.

A spurious response is as high as about 1.0 in the region surrounded by the elliptical portion J in FIG. 29. As is seen from FIG. 29, when the fractional bandwidth exceeds, for example, about 0.17, that is, about 17%, a large spurious response of about 1 or larger is observed within the pass band even if the parameter, that is, the fractional bandwidth, is changed. That is, as in the resonance characteristics in FIG. 28, a large spurious response indicated by the arrow B is observed within the pass band. Accordingly, the fractional bandwidth is preferably, for example, about 17% or lower. In this case, the spurious response can be reduced by the adjustment of the film thickness of the piezoelectric layer 2 and the dimensions of electrodes 3 and 4, for example.

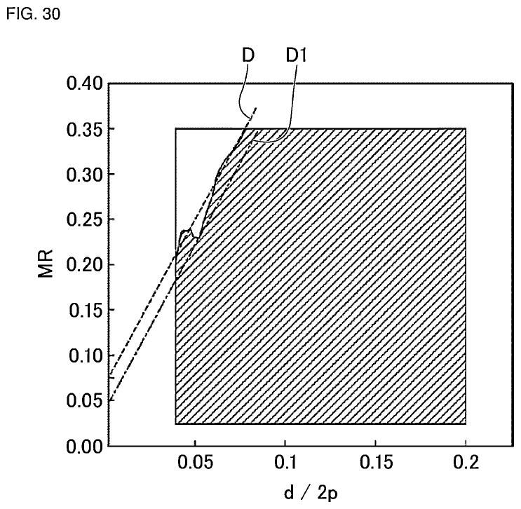

FIG. 30 is a graph illustrating the relationships between d/2p, the metallization ratio MR, and the fractional bandwidth. Based on the above-described acoustic wave device, various acoustic wave devices were made by changing d/2p and MR. Then, the fractional bandwidth was measured.

The hatched portion on the right side of the broken line D in FIG. 30 is a region where the fractional bandwidth is about 17% or lower. The boundary between the hatched portion and a portion without can be expressed by MR=about 3.5(d/2p)+0.075, that is, MR=about 1.75(d/p)+0.075. Preferably, for example, MR≤about 1.75(d/p)+0.075, in which case, the fractional bandwidth is likely to be about 17% or lower. More preferably, for example, the region where the fractional bandwidth is about 17% or lower is the region on the right side of the boundary expressed by MR=about 3.5(d/2p)+0.05, which is indicated by the long dashed dotted line D1 in FIG. 30. That is, if MR about 1.75(d/p)+0.05, the fractional bandwidth can reliably be about 17% or lower.

FIG. 31 is a graph illustrating a map of the fractional bandwidth with respect to the Euler angles (0°, θ, ψ) of LiNbO₃ in a case in which d/p is approached as close to 0 as possible.

The hatched portions in FIG. 31 are regions where a fractional bandwidth of at least about 5% or higher is obtained. The ranges of the regions can be approximated to the ranges represented by the following expressions (1), (2), and (3).

(0°±10°, 0° to 20°, a desirable angle of ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)

(0°±10°, [180°−30° (1−(ψ−90)²/8100)^{1/2}] to 180°, a desirable angle of ψ) Expression (3)

When the Euler angles are in the range represented by the above-described expression (1), (2), or (3), a sufficiently wide fractional bandwidth can be obtained, which is preferable.

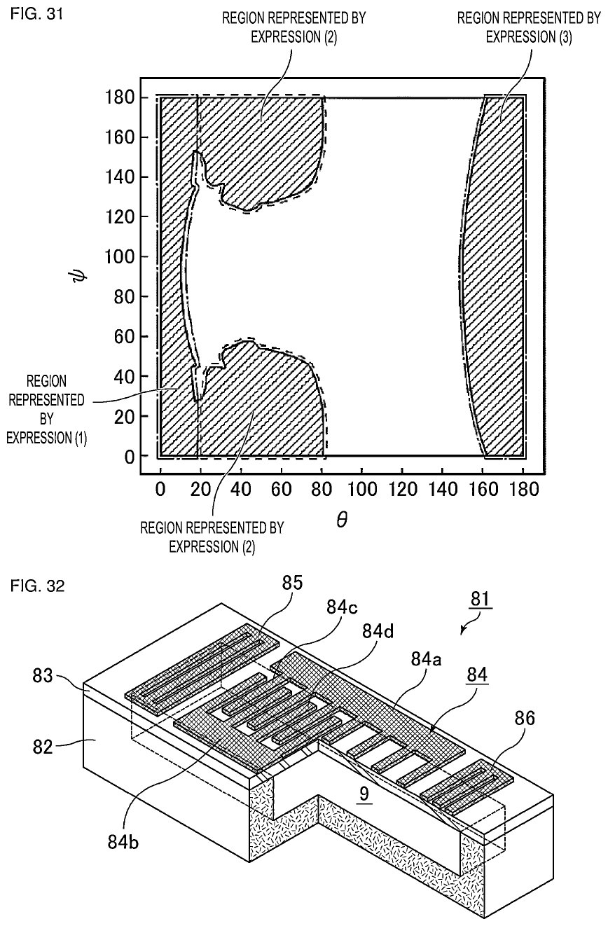

FIG. 32 is a partial cutaway perspective view for explaining an example of an acoustic wave device utilizing a Lamb wave.

An acoustic wave device 81 includes a support substrate 82. A recessed portion opened above is provided in the support substrate 82. A piezoelectric layer 83 is stacked on the support substrate 82. With this configuration, a hollow portion 9 is provided. An IDT electrode 84 is provided on the piezoelectric layer 83 so that it is located above the hollow portion 9. A reflector 85 is provided on one side of the IDT electrode 84 in the propagation direction of an acoustic wave, while a reflector 86 is provided on the other side of the IDT electrode 84 in the propagation direction. In FIG. 32, the outer peripheral edges of the hollow portion 9 are indicated by the broken lines. The IDT electrode 84 includes a first busbar electrode 84a, a second busbar electrode 84b, electrodes 84c, which are a plurality of first electrode fingers, and electrodes 84d, which are a plurality of second electrode fingers. The plurality of electrodes 84c are connected to the first busbar electrode 84a. The plurality of electrodes 84d are connected to the second busbar electrode 84b. The plurality of electrodes 84c and the plurality of electrodes 84d are interdigitated with each other.

In the acoustic wave device 81, a Lamb wave is excited with the application of an AC electric field to the IDT electrode 84 disposed above the hollow portion 9. Since the reflectors 85 and 86 are disposed on both sides of the IDT electrode 84, resonance characteristics based on the Lamb wave can be obtained.

As described above, acoustic wave devices according to preferred embodiments of the invention may be acoustic wave devices using a Lamb wave.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface opposing each other;
a plurality of electrodes on the first main surface of the piezoelectric layer;
a support substrate stacked directly or indirectly on the second main surface of the piezoelectric layer;
a first cover section separated from the first main surface of the piezoelectric layer with a space therebetween; and
a first support section between the first cover section and the piezoelectric layer or the support substrate; wherein
the plurality of electrodes include at least one pair of functional electrodes and wiring electrodes, each of the wiring electrodes being connected to a corresponding functional electrode;
the at least one pair of functional electrodes includes a first functional electrode and a second functional electrode facing each other in an intersecting direction, the intersecting direction being a direction intersecting with a stacking direction of the support substrate and the piezoelectric layer;
the wiring electrodes include a first wiring electrode connected to the first functional electrode and a second wiring electrode connected to the second functional electrode;
a hollow portion is provided between the support substrate and the piezoelectric layer;
as viewed in the stacking direction of the support substrate and the piezoelectric layer, at least a portion of the first functional electrode and at least a portion of the second functional electrode overlap the hollow portion;
as viewed in the stacking direction of the support substrate and the piezoelectric layer, the first cover section overlaps the first and second functional electrodes and the first and second wiring electrodes;
a first relay electrode, which is to be electrically connected to the first functional electrode, and a second relay electrode, which is to be electrically connected to the second functional electrode, are provided on a main surface of the first cover section on a side adjacent to the piezoelectric layer; and
as viewed in the stacking direction of the support substrate and the piezoelectric layer, at least a portion of the first relay electrode overlaps at least one of the first functional electrode and the second functional electrode.

2. The acoustic wave device according to claim 1, wherein, as viewed in the stacking direction of the support substrate and the piezoelectric layer, at least a portion of the second relay electrode overlaps at least one of the first functional electrode and the second functional electrode.

3. The acoustic wave device according to claim 1, wherein the first relay electrode and the second relay electrode face each other in the intersecting direction on a main surface of the first cover section on a side adjacent to the piezoelectric layer.

4. The acoustic wave device according to claim 3, wherein
the first relay electrode includes at least one third electrode and a third busbar electrode, the at least one third electrode being connected to the third busbar electrode; and
the second relay electrode includes at least one fourth electrode and a fourth busbar electrode, the at least one fourth electrode being connected to the fourth busbar electrode.

5. The acoustic wave device according to claim 1, wherein the first relay electrode and the second relay electrode face each other in the stacking direction of the support substrate and the piezoelectric layer.

6. The acoustic wave device according to claim 5, further comprising a dielectric film between the first relay electrode and the second relay electrode.

7. An acoustic wave device comprising:
a piezoelectric layer including a first main surface and a second main surface opposing each other;
a plurality of electrodes on the first main surface of the piezoelectric layer;
a support substrate stacked directly or indirectly on the second main surface of the piezoelectric layer;
a first cover section separated from the first main surface of the piezoelectric layer with a space therebetween; and
a first support section between the first cover section and the piezoelectric layer or the support substrate; wherein
the plurality of electrodes include at least one pair of functional electrodes and wiring electrodes, each of the wiring electrodes being connected to a corresponding functional electrode;
the at least one pair of functional electrodes includes a first functional electrode and a second functional electrode facing each other in an intersecting direction, the intersecting direction being a direction intersecting with a stacking direction of the support substrate and the piezoelectric layer;
the wiring electrodes include a first wiring electrode connected to the first functional electrode and a second wiring electrode connected to the second functional electrode;
a hollow portion is provided between the support substrate and the piezoelectric layer;
as viewed in the stacking direction of the support substrate and the piezoelectric layer, at least a portion of the first functional electrode and at least a portion of the second functional electrode overlap the hollow portion;
as viewed in the stacking direction of the support substrate and the piezoelectric layer, the first cover section overlaps the first and second functional electrodes and the first and second wiring electrodes;
a first relay electrode, which is to be electrically connected to the first functional electrode, and a second relay electrode, which is to be electrically connected to the second functional electrode, are provided on a main surface of the first cover section on a side adjacent to the piezoelectric layer; and
the first relay electrode and the second relay electrode face each other in the intersecting direction on a main surface of the first cover section on a side adjacent to the piezoelectric layer, or face each other in the stacking direction of the support substrate and the piezoelectric layer.

8. The acoustic wave device according to claim 1, wherein
the hollow portion passes through the support substrate; and
the acoustic wave device further comprising:
a second cover section adjacent to a surface of the support substrate opposite a surface of the support substrate close to the piezoelectric layer and that closes the hollow portion; and
a second support section between the second cover section and the support substrate.

9. The acoustic wave device according to claim 1, wherein
the first functional electrode includes at least one first electrode and a first busbar electrode, the at least one first electrode being connected to the first busbar electrode; and
the second functional electrode includes at least one second electrode and a second busbar electrode, the at least one second electrode being connected to the second busbar electrode.

10. The acoustic wave device according to claim 9, wherein a thickness of the piezoelectric layer is about 2p or smaller, where p is a center-to-center distance between a first electrode of the at least one first electrode and a second electrode of the at least one second electrode, the first electrode and the second electrode being adjacent to each other.

11. The acoustic wave device according to claim 1, wherein the piezoelectric layer is made of lithium niobate or lithium tantalate.

12. The acoustic wave device according to claim 11, wherein the acoustic wave device is structured to generate a bulk wave of a thickness shear mode.

13. The acoustic wave device according to claim 9, wherein d/p about ≤0.5, where d is a thickness of the piezoelectric layer and p is a center-to-center distance between a first electrode of the at least one first electrode and a second electrode of the at least one second electrode, the first electrode and the second electrode being adjacent to each other.

14. The acoustic wave device according to claim 13, wherein d/p≤about 0.24.

15. The acoustic wave device according to claim 9, wherein MR≤about 1.75(d/p)+0.075, where d is a thickness of the piezoelectric layer, p is a center-to-center distance between a first electrode of the at least one first electrode and a second electrode of the at least one second electrode, the first electrode and the second electrode being adjacent to each other, and MR is a metallization ratio, which is a ratio of an area of the adjacent first and second electrodes to an area of an excitation region where the adjacent first and second electrodes overlap each other as seen in a facing direction of the adjacent first and second electrodes.

16. The acoustic wave device according to claim 15, wherein MR≤about 1.75(d/p)+0.05.

17. The acoustic wave device according to claim 11, wherein Euler angles (φ, θ, ψ) of the lithium niobate or the lithium tantalate are in a range represented by expression (1), (2), or (3):
(0°±10°, 0° to 20°, a desirable angle of ψ) Expression (1);
(0°±10°, 20° to 80°, 0° to 60° (1−(θ−50)²/900)^{1/2}) or (0°±20° to 80°, [180°−60° (1−(θ−50)²/900)^{1/2}] to 180°) Expression (2); and
(0°±10°, [180°−30° (1−(ψ−90)²/8100)^{1/2}] to 180°, a desirable angle of ψ) Expression (3).

18. The acoustic wave device according to claim 1, wherein a dielectric film is provided between a main surface of the first cover section on a side adjacent to the piezoelectric layer, and at least one of the first relay electrode and the second relay electrode.

19. The acoustic wave device according to claim 7, wherein the piezoelectric layer is made of lithium niobate or lithium tantalate.

20. The acoustic wave device according to claim 19, wherein the acoustic wave device is structured to generate a bulk wave of a thickness shear mode.
